(19) United States
(12) Patent Application Publication
(10) Pub. No.: US 2024/0012023 A1
(43) Pub. Date: Jan. 11, 2024

(54) CONTACTOR AND METHOD OF MANUFACTURING THE SAME

(71) Applicant: WITHMEMS CO., LTD., Hwaseong-si (KR)

(72) Inventors: Hwang Sub KOO, Suwon-si (KR); Jong Koon PARK, Yongin-si (KR); Ki Sang YUN, Hwaseong-si (KR); Kyung Ho KIM, Yongin-si (KR)

(73) Assignee: WITHMEMS CO., LTD., Hwaseong-si (KR)

(21) Appl. No.: 18/372,184

(22) Filed: Sep. 25, 2023

Related U.S. Application Data
(63) Continuation of application No. PCT/KR2022/004411, filed on Mar. 29, 2022.

(30) Foreign Application Priority Data
Mar. 29, 2021 (KR) 10-2021-0040532

(51) Int. Cl. G01R 1/04; H01R 9/05

(52) U.S. Cl. CPC G01R 1/0416; H01R 9/0503; H01R 9/0524

(57) ABSTRACT

A contactor for connection and signal transfer between conductors includes: a core part configured to extend in a longitudinal direction, contain a conductive particle and be formed to be elastically deformable; an insulation part configured to surround a transverse surface of the core part and be formed to be elastically deformable; and a shield part configured to surround a transverse surface of the insulation part to be spaced apart from the core part, contain a conductive particle and be formed to be elastically deformable.

### CROSS-REFERENCE TO RELATED APPLICATIONS

This application is a continuation of International Application No. PCT/KR2022/004411 filed on Mar. 29, 2022, which claims priority to Korean Patent Application No. 10-2021-0040532 filed on Mar. 29, 2021, the entire contents of which are herein incorporated by reference.

### TECHNICAL FIELD

The present disclosure relates to a contactor that performs connection and signal transfer between conductors, and a method of manufacturing the same.

### BACKGROUND

A coaxial cable is a type of transmission line and is to supplement 2-wire parallel cable having a defect in that effective resistance of a conduct wire increases at a high frequency due to skin effect. FIG. 1 is a diagram illustrating a coaxial cable and a connector assembled to the coaxial cable. In general, a coaxial cable 10 includes two cylindrical conductors and an insulator which share a central axis. A central conductor of the coaxial cable 10 is for actual signal transfer, and the insulator surrounding the central conductor is to fill between the central conductor and an external conductor and insulate them. The external conductor surrounding the insulator is configured as a metallic shield (mesh) for shielding. For example, the external conductor may be formed of net-shaped aluminum or copper.

Referring to FIG. 1, a metallic connector 20 connected to an end portion of the coaxial cable 10 includes a central pin, an insulator surrounding the pin, and a terminal surrounding the insulator. The connector 20 is for mechanical and electrical connection between conductors and may be designed in various shapes, such as M-type connector, N-type connector, and F-type connector, depending on the use.

However, as for the conventional coaxial cable 10 and connector 20, it is complicated to manufacture and assemble individual components, and the conventional coaxial cable 10 and connector 20 do not include components that are formed to be elastically deformable and make a close contact with each other. Therefore, the conventional coaxial cable 10 and connector 20 cannot secure connection between conductors.

### DISCLOSURE OF THE INVENTION

### Problems to be Solved by the Invention

The present disclosure is to solve the above-described problems of the prior art, and to provide a contactor that performs connection and signal transfer between conductors and is formed to be elastically deformable, and a method of manufacturing the same.

Also, the present disclosure is also to provide a contactor that is integrally formed for connection and signal transfer between conductors, and a method of manufacturing the same.

However, the problems to be solved by the present disclosure are not limited to the above-described problems, and there may be other problems to be solved by the present disclosure.

### Means for Solving the Problems

As a means for achieving the above-described technical problems, an embodiment of the present disclosure provides a contactor for connection and signal transfer between conductors, including, a core part configured to extend in a longitudinal direction, contain a conductive particle and be formed to be elastically deformable; an insulation part configured to surround a transverse surface of the core part and be formed to be elastically deformable; and a shield part configured to surround a transverse surface of the insulation part to be spaced apart from the core part, contain a conductive particle and be formed to be elastically deformable.

Another embodiment of the present disclosure provides a method of manufacturing a contactor for connection and signal transfer between conductors, including, forming a core part configured to extend in a longitudinal direction, contain a conductive particle and be elastically deformable; forming an insulation part configured to surround a transverse surface of the core part and be elastically deformable; and forming a shield part configured to surround a transverse surface of the insulation part to be spaced apart from the core part, contain a conductive particle and be elastically deformable.

The above-described technical solutions are provided by way of illustration only and should not be construed as liming the present disclosure. Besides the above-described embodiments, there may be additional embodiments described in the accompanying drawings and the detailed description.

### Effects of the Invention

According to any one of the above-described means for solving the problems of the present disclosure, it is possible to secure reliable connection and reduce a contact resistance by being pressed and being in close contact with the structure through elastic deformation. Also, it is possible to provide a contactor and a method of manufacturing the same capable of achieving effective interconnection even if there is a tolerance of a contact surface or a difference in shape.

Also, according to any one of the above-described means for solving the problems of the present disclosure, a core part, an insulation part, and a shield part are bonded to each other and integrally formed, and thus, an assembly process can be omitted and manufacturing costs can be reduced. Further, it is possible to provide a contactor and a method of manufacturing the same capable of manufacturing each of the core part, the insulation part, and the shield part in various shapes and properties.

### BRIEF DESCRIPTION OF THE DRAWINGS

FIG. 1 is a diagram illustrating a coaxial cable and a connector assembled to the coaxial cable.

FIG. 2 is a diagram illustrating a contactor according to an embodiment of the present disclosure.

FIG. 3 is a diagram illustrating a contactor according to another embodiment of the present disclosure.

FIG. 4 is a diagram illustrating a contactor according to yet another embodiment of the present disclosure.

FIG. 5 is a flowchart showing a method of manufacturing a contactor according to the present disclosure.

FIG. 6 is a diagram illustrating steps of the method of manufacturing a contactor shown in FIG. 5.

FIG. 7 is a diagram illustrating steps of the method of manufacturing a contactor shown in FIG. 5.

FIG. 8 is a diagram illustrating steps of the method of manufacturing a contactor shown in FIG. 5.

FIG. 9 is a diagram illustrating steps of the method of manufacturing a contactor shown in FIG. 5.

FIG. 10 is a diagram illustrating steps of the method of manufacturing a contactor shown in FIG. 5.

FIG. 11 is a diagram illustrating steps of the method of manufacturing a contactor shown in FIG. 5.

FIG. 12 is a diagram illustrating steps of the method of manufacturing a contactor shown in FIG. 5.

FIG. 13 is a diagram illustrating steps of the method of manufacturing a contactor shown in FIG. 5.

FIG. 14 is a diagram illustrating steps of the method of manufacturing a contactor shown in FIG. 5.

### DETAILED DESCRIPTION THE INVENTION

Hereinafter, embodiments of the present disclosure will be described in detail with reference to the accompanying drawings to be readily implemented by a person with ordinary skill in the art to which the present invention belongs. However, it is to be noted that the present disclosure is not limited to the example embodiments but can be embodied in various other ways. In the drawings, parts irrelevant to the description are omitted in order to clearly explain the present disclosure, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element. Further, it is to be understood that the term “comprises or includes” and/or “comprising or including” used in the document means that one or more other components, steps, operation and/or existence or addition of elements are not excluded in addition to the described components, steps, operation and/or elements unless context dictates otherwise and is not intended to preclude the possibility that one or more other features, numbers, steps, operations, components, parts, or combinations thereof may exist or may be added.

Hereinafter, embodiments of the present disclosure will be described in detail with reference to the accompanying drawings.

FIG. 2 is a diagram illustrating a contactor according to an embodiment of the present disclosure. A contactor 100 according to the present disclosure may include a core part 110, an insulation part 120, and a shield part 130. Referring to FIG. 2, the core part 110, the insulation part 120, and the shield part 130 are concentrically cylindrical. For example, the core part 110, the insulation part 120, and the shield part 130 designed to be concentrically cylindrical according to an embodiment of the present disclosure may share a central axis.

The core part 110, the insulation part 120, and the shield part 130 according to an embodiment of the present disclosure may be hardened by a phase change and integrally formed with each other. For example, the core part 110, the insulation part 120, and the shield part 130 which are in a liquid phase may change to a solid phase, and may become hardened as the viscosity increases. The contactor 100 may form a structure in which the core part 110, the insulation part 120, and the shield part 130 are directly bonded to each other as one body through a phase change.

As described above, the contactor 100 according to the present disclosure is manufactured such that the core part 110, the insulation part 120, and the shield part 130 are connected to each other as one body, so that an assembly process can be omitted and manufacturing costs can be reduced, and also, each of the core part 110, the insulation part 120, and the shield part 130 can be manufactured in various shapes. Hereinafter, each of the components will be described.

The core part 110 according to an embodiment of the present disclosure may extend in a longitudinal direction, contain a conductive particle and may be formed to be elastically deformable. The core part 110 may serve as a conducting wire for signal transfer. Also, the shield part 130 according to an embodiment of the present disclosure may surround a transverse surface of the insulation part 120 to be spaced apart from the core part 110, contain a conductive particle and may be formed to be elastically deformable. The shield part 130 may be formed of a conductive material and may serve to shield interference during signal transmission of the core part 110.

For example, the core part 110 and the shield part 130 may be formed of a material including silicone containing a conductive particle. The core part 110 and the shield part 130 may include various types of polymer materials. The core part 110 and the shield part 130 may be formed of diene type rubber such as silicone, polybutadiene, polyisoprene, SBR, NBR, and hydrogen compounds thereof, or may be formed of a block copolymer such as a styrene butadiene block copolymer, a styrene isoprene block copolymer, and hydrogen compounds thereof. Also, the core part 110 and the shield part 130 may be formed of chloroprene, urethane rubber, polyethylene-based rubber, epichlorohydrin rubber, an ethylene-propylene copolymer, an ethylene propylene diene copolymer, and the like.

Further, the conductive particles contained in the core part 110 and the shield part 130 according to an embodiment of the present disclosure may be aligned in the longitudinal direction. For example, the conductive particles may be formed of a single conductive metal material, such as iron, copper, zinc, chromium, nickel, silver, cobalt, and aluminum, or an alloy of two or more of them, which are ferromagnetic materials. Furthermore, the conductive particles may be prepared by coating the surface of a core metal with a highly conductive metal, such as gold, silver, rhodium, palladium, platinum, or silver and gold, silver and rhodium, and silver and palladium. The conductive particles may further include a MEMS tip, flake, wire rod, carbon nanotube (CNT), graphene, etc. in order to improve conductivity.

The insulation part 120 according to an embodiment of the present disclosure may surround a transverse surface of the core part 110 and may be formed to be elastically deformable. Referring to FIG. 2, the insulation part 120 may be designed to fill between the core part 110 and the shield part 130 and insulate them. The insulation part 120 may serve to secure insulation between the core part 110 and the shield part 130. For example, the insulation part 120 may be formed of an insulator, such as glass, ebonite, or rubber, which does not transfer heat or electricity. Further, the insulation part 120 may be formed of an insulating material such as polyethylene (PE), polyvinyl chloride (PVC), an ethylene-propylene elastic copolymer (EPR), and the like.

As described above, the contactor 100 according to the present disclosure including the core part 110, the insulation part 120, and the shield part 130 which are elastically deformable, is elastically deformable in the longitudinal direction and a transverse direction during connection between conductors, and thus, can secure connection with a structure and reduce a contact resistance by being pressed to be in close contact with the structure. Also, the contactor 100 can achieve effective interconnection even if there is a tolerance of a contact surface or a difference in shape.

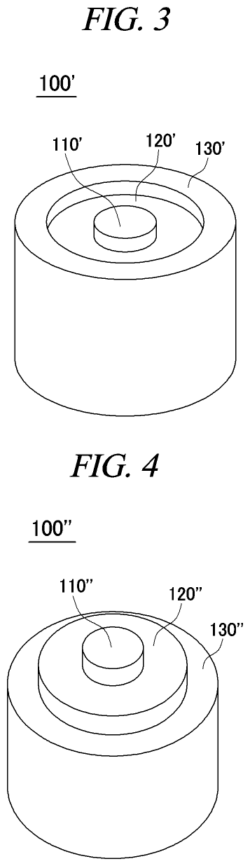

FIG. 3 is a diagram illustrating a contactor according to another embodiment of the present disclosure. Referring to FIG. 3, a contactor 100′ according to another embodiment of the present disclosure may be designed such that each of a core part 110′ and a shield part 130′ protrudes in the longitudinal direction compared to an insulation part 120′.

For example, the contactor 100′ according to the present disclosure as illustrated in FIG. 3 includes the core part 110′ and the shield part 130′ which protrude compared to the insulation part 120′, and, thus, it is possible to overcome contact instability in electrical connection between conductors. Since the contactor 100′ illustrated in FIG. 3 includes the core part 110′ and the shield part 130′ which contain the conductive particles and protrude compared to the insulation part 120′, it is possible to achieve a stable contact with a conductor (e.g., a terminal of a pad of an inspection target object). Specifically, when the core part 110′ and the shield part 130′ are compressed by a pressure in the longitudinal direction during a contact with a conductor, the particles contained in the longitudinal direction may make a contact with each other to impart electrical conductivity in the longitudinal direction. Since the contactor 100′ according to the present disclosure includes the core part 110′ and the shield part 130′ which protrude in the longitudinal direction compared to the insulation part 120′, it is possible to further increase electrical conductivity.

FIG. 4 is a diagram illustrating a contactor according to yet another embodiment of the present disclosure. Referring to FIG. 4, an insulation part 120″ of a contactor 100″ according to yet another embodiment of the present disclosure may protrude in the longitudinal direction compared to a shield part 130″, and a core part 110″ may protrude in the longitudinal direction compared to the insulation part 120″.

For example, the contactor 100″ according to the present disclosure as illustrated in FIG. 4 may include the core part 110″ protruding compared to the other components, i.e., have a smaller cross-sectional area of a portion in direct contact with a conductor so as to correspond to pads or terminals with a fine pitch and may increase in contact area and vary in shape for assembly to a counterpart. In the contactor 100″ illustrated in FIG. 4, both end portions to be in contact with the conductor may be formed to have a smaller diameter. Thus, it is possible to avoid interference with peripheral components and also possible to minimize leakage current between adjacent pins. Therefore, the contactor 100″ according to the present disclosure enables a close connection between conductors and each contactor 100″ can be individually operated with a high precision, which improves the precision between the conductors.

The core part 110, the insulation part 120, and the shield part 130 according to an embodiment of the present disclosure may be designed to be different from each other in at least one of physical properties including hardness, Young's modulus, and resistivity. For example, the hardness and the Young's modulus of the core part 110 or the shield part 130 to be in direct contact with a terminal may be designed to be higher than those of the other components, and, thus, it is possible to improve the precision in connection and also possible to suppress deformation or damage caused by repeated uses.

Further, the core part 110 and the shield part 130 according to an embodiment of the present disclosure may be designed to be different from each other in properties (e.g., material, size, density, etc.) of the contained conductive particles, respectively. For example, regarding the material of the conductive particle, the core part 110 or the shield part 130 may employ a nickel particle for effective alignment of conductive particles or may employ a copper particle if necessary to improve electrical conductivity. The core part 110 or the shield part 130 may also employ a silica-coated particle for weight lightening.

For another example, regarding the size of the conductive particle, conductive particles having a greater size are generally easy to process and excellent in terms of electrical conductivity. However, conductive particles having a smaller size can be relatively uniformly distributed even in a member having a fine diameter and thus can improve the hardness or Young's modulus of the member. In view of these characteristics, the contactor 100 according to the present disclosure may be designed to include the core part 110 and the shield part 130 each having different hardness or Young's modulus by varying the material, size, and density of conductive particles contained therein.

As described above, in the contactor 100 according to the present disclosure, the core part 110 and the shield part 130 designed to have different physical properties from each other may satisfy various design requirements for a probe pin. That is, the core part 110 and the shield part 130 different from each other in physical properties may be formed respectively corresponding to a part requiring an excellent hardness and a part where elastic deformation is allowed.

Therefore, the contactor 100 according to the present disclosure can secure connection with a structure and reduce a contact resistance by being pressed to be in close contact with the structure through elastic deformation. Also, the contactor 100 can achieve effective interconnection even if there is a tolerance of a contact surface or a difference in shape.

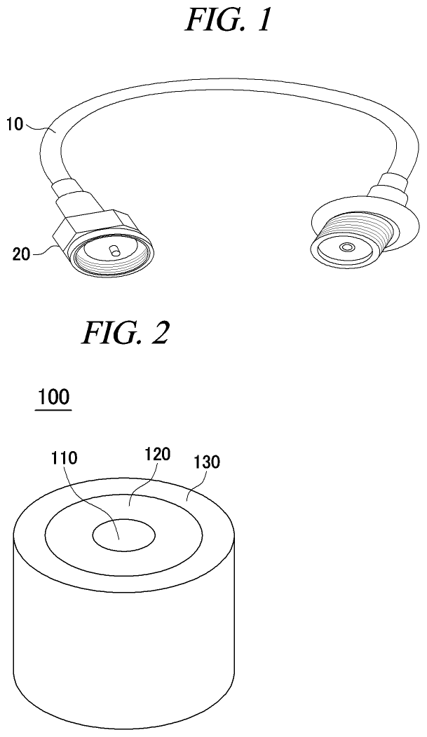

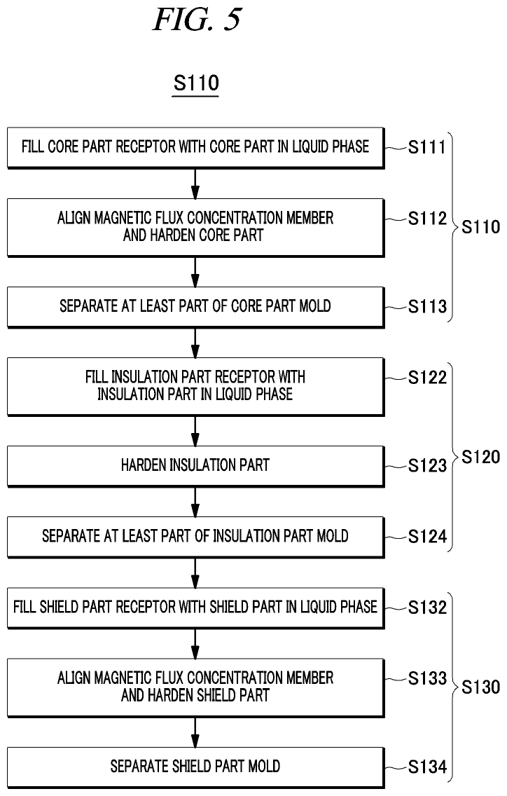

FIG. 5 is a flowchart showing a method of manufacturing a contactor according to the present disclosure. The method of manufacturing a contactor (S100) illustrated in FIG. 5 includes the steps time-sequentially performed according to the embodiment illustrated in FIG. 1 to FIG. 4. Therefore, the above descriptions of the steps may also be applied to the method of manufacturing a contactor for connection and signal transfer between conductors (S100) according to the embodiment illustrated in FIG. 1 to FIG. 4 even though they are omitted hereinafter.

In a step S110, the core part 110 which extends in a longitudinal direction, contains a conductive particle and is elastically deformable may be formed.

In a step S120, the insulation part 120 which surrounds a transverse surface of the core part 110 and is elastically deformable may be formed.

In a step S130, the shield part 130 which surrounds a transverse surface of the insulation part 120 to be spaced apart from the core part 110, contains a conductive particle and is elastically deformable may be formed.

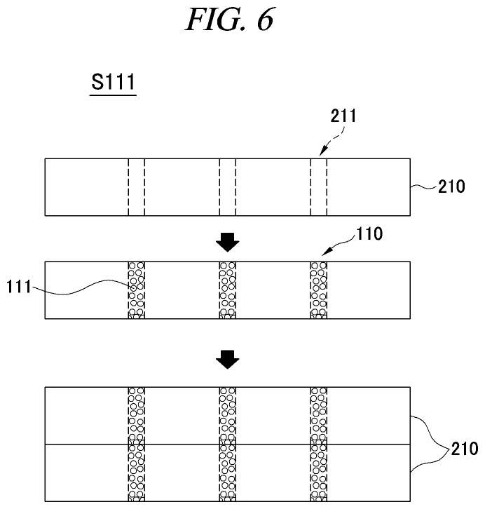

Hereinafter, the steps S110 to S130 will be described in detail. FIG. 6 to FIG. 14 are diagrams illustrating steps of the method of manufacturing a contactor shown in FIG. 5. First, FIG. 6 to FIG. 8 are diagrams illustrating the step S110 of forming the core part shown in FIG. 5. Referring to FIG. 6, the step S110 of forming the core part may include a step S111 of filling a core receptor 211 of a core part mold 210 with the core part 110 in a liquid phase containing a conductive particle 111. Herein, the core part mold 210 may be formed of metals or resins which are not magnetic. For example, the core part mold 210 may be formed of aluminum (AI) or Torlon.

For example, the core part 110 in a liquid phase may contain the conductive particle 111. The conductive particles 111 may be distributed inside the core part 110, and may be aligned in the longitudinal direction of the core part 110 through the following step. The conductive particles 111 may make a contact with each other to impart conductivity to the core part 110 in the longitudinal direction. When the core part 110 is compressed by a pressure in the longitudinal direction to inspect the inspection target object which is an electrical component, the conductive particles 111 may get closer to each other and electrical conductivity of the core part 110 may increase in the longitudinal direction.

Referring to FIG. 6, in the step S111, for example, the core receptor 211 may be filled with the core part 110 in a liquid phase, and a plurality of core part molds 210 filled with the core part 110 in a liquid phase may be stacked to increase the length of the core part 110. For another example, the plurality of core part molds 210 may be aligned or stacked and then, the core receptor 211 may be filled with the core part 110 in a liquid phase.

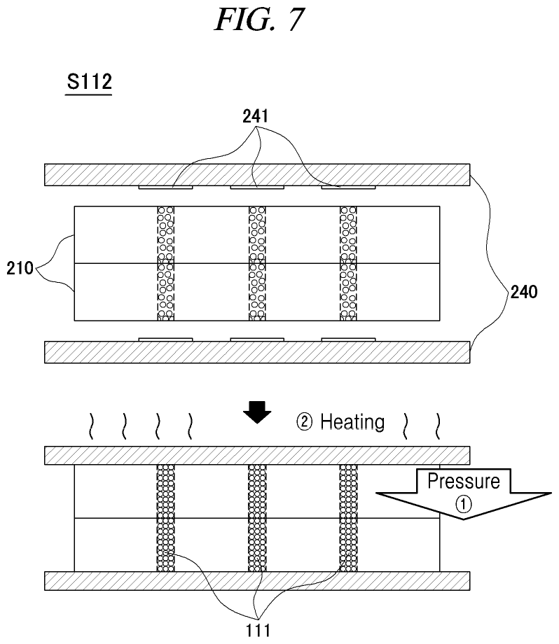

Referring to FIG. 7, the step S110 of forming the core part may further include a step S112 of aligning a magnetic flux concentration member 240 including magnetic pads 241 at positions corresponding to the core receptors 211 and hardening the core part 110. For example, the magnetic flux concentration member 240 may include a plurality of magnetic pads 241 placed at predetermined intervals on the member. Herein, the magnetic pads 241 may be formed of a magnetic material, such as nickel (Ni), a nickel-cobalt alloy (NiCo), and iron (Fe). In this case, the magnetic flux concentration member 240 may be formed of a ferrimagnetic material to induce the concentration of magnetic flux on the magnetic pads 241.

In the step S112, the magnetic flux concentration member 240 may come in close contact with the core part mold 210 in order for the magnetic pads 241 to close the core receptors 211. For example, the magnetic flux concentration member 240 may be brought into close contact with an upper end and a lower end of the core part mold 210 in which the core receptors 211 are filled with the core part 110 in a liquid phase. The magnetic pads 241 may be configured to concentrate magnetic flux of the contactor 100 according to the present disclosure.

In the step S112, the core part 110 in a liquid phase may be hardened at a predetermined pressure and predetermined temperature. For example, the magnetic flux concentration member 240 may apply at least one of heat and pressure to the core part 110 in a liquid phase. The core part 110 in a liquid phase filled in each layer of the plurality of core part molds 210 may be integrally formed with each other through a phase change caused by at least one of the applied heat and pressure. That is, the core part 110 in a liquid phase may be hardened by applying heat and pressure to the magnetic flux concentration member 240 in close contact with the core part molds 210. In this case, as illustrated in FIG. 7, the conductive particles may be rearranged and aligned in the longitudinal direction by magnetic flux.

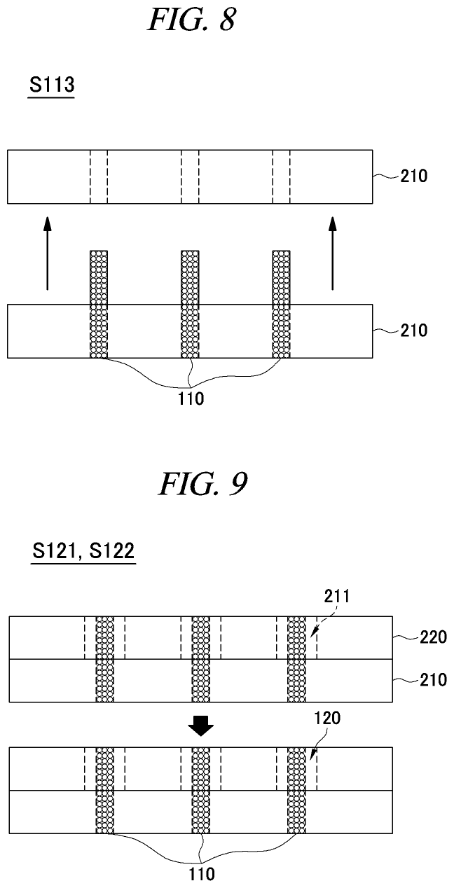

Referring to FIG. 8, the step S110 of forming the core part may further include a step S113 of separating at least a part of the core part mold 210 from the core part 110. For example, in the step S113, the core part 110 in a liquid phase filled in each of the plurality of core part molds 210 and integrally formed with each other may be separated from the core part molds 210. In this case, the manufactured core part 110 can be separated from the core part molds 210 more easily by removing the plurality of stacked core part molds 210 one by one without damage to the core part 110.

FIG. 9 to FIG. 12 are diagrams illustrating the step S120 of forming the insulation part shown in FIG. 5. First, referring to FIG. 9, the step S120 of forming the insulation part may include a step S121 of aligning an insulation part mold 220 on the core part mold 210 in order for a part of the core part 110 to be inserted into an insulation receptor 221 of the insulation part mold 220 while another part of the core part 110 is supported by the core part mold 210. For example, in the step S121, when the core part 110 is completely manufactured, some of the plurality of stacked core part molds 210 may be removed to stack the insulation part mold 220 including the insulation receptor 221. The remaining core part molds 210 may serve to support the core part 110 when the insulation part mold 220 is stacked.

The step S120 of forming the insulation part may further include a step S122 of filling the insulation receptor 221 of the insulation part mold 220 with the insulation part 120 in a liquid phase. For example, referring to FIG. 9, the insulation receptor 221 of the stacked insulation part mold 220 may be filled with the insulation part 120 in a liquid phase in the step S122.

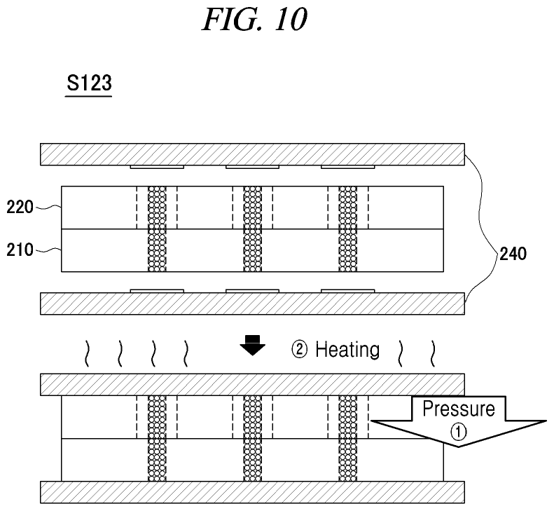

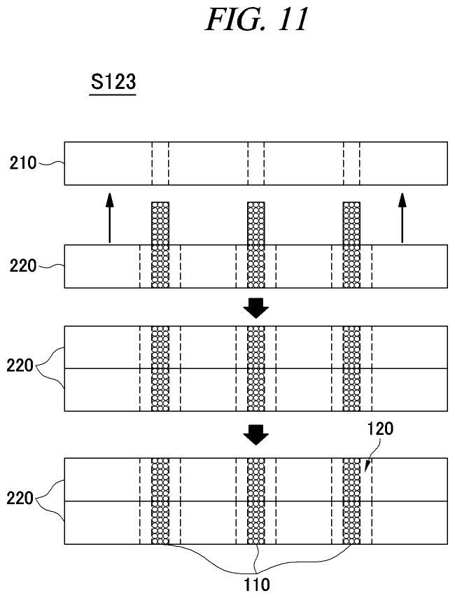

Referring to FIG. 10 and FIG. 11, the step S120 of forming the insulation part may further include a step S123 of hardening the insulation part 120. In the step S123, the magnetic flux concentration member 240 including the magnetic pads 241 at positions corresponding to the insulation receptors 221 may be aligned and the insulation part 120 may be hardened. For example, the magnetic flux concentration member 240 may be brought into close contact with the insulation part mold 220 in order for the magnetic pads 241 to close the insulation receptors 221 filled with the insulation part 120 in a liquid phase. In this case, the magnetic flux concentration member 240 may be omitted if there is no need to concentrate magnetic flux.

Referring to FIG. 10, in the step S123, the magnetic flux concentration member 240 may be brought into close contact with an upper end and a lower end of a mold in which the insulation part mold 220 and the core part mold 210 are stacked, and the insulation part 120 in a liquid phase may be hardened at a predetermined pressure and predetermined temperature. For example, the magnetic flux concentration member 240 may apply at least one of heat and pressure to the insulation part 120 in a liquid phase, and the insulation part 120 in a liquid phase may be hardened to be integrally formed with the core part 110 through a phase change caused by at least one of the heat and pressure applied to the insulation part 120 in a liquid phase.

Referring to FIG. 11, in the step S123, the insulation part mold 220 may be aligned in order for a part of the core part 110 to be inserted into the insulation receptor 221 of the insulation part mold 220 while another part of the core part 110 is supported by the insulation part mold 220. As described above, the insulation receptor 221 of the aligned insulation part mold 220 may be filled with the insulation part 120 in a liquid phase, and the insulation part 120 in a liquid phase may be hardened at a predetermined pressure and predetermined temperature.

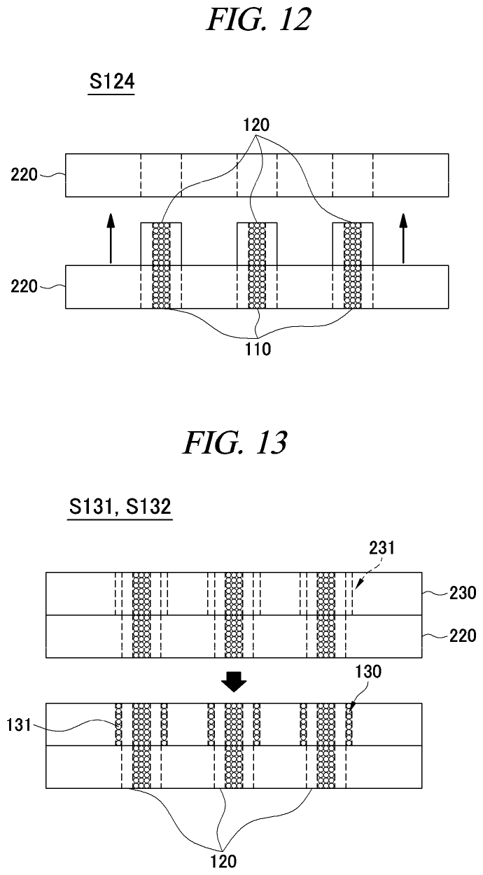

Referring to FIG. 12, the step S120 of forming the insulation part may further include a step S124 of separating at least a part of the insulation part mold 220 from the insulation part 120. For example, in the step S124, when the insulation part 120 is completely manufactured, some of a plurality of stacked insulation part molds 220 may be removed.

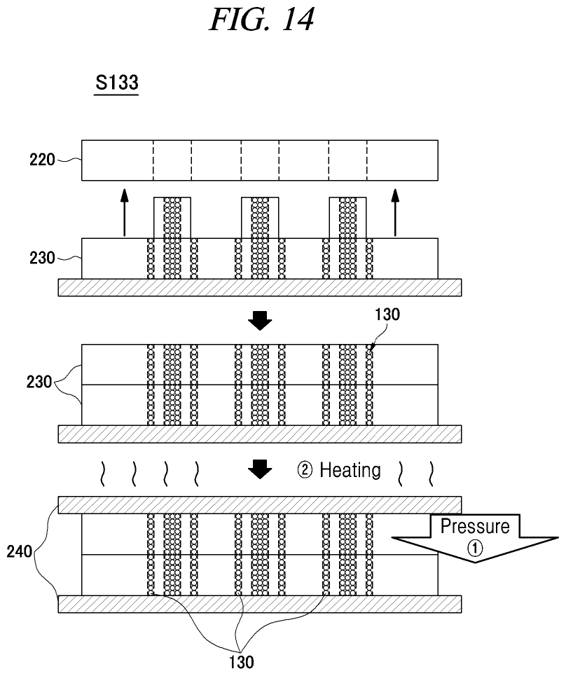

FIG. 13 and FIG. 14 are diagrams illustrating the step S130 of forming the shield part shown in FIG. 5. First, referring to FIG. 3, the step S130 of forming the shield part may include a step S131 of aligning a shield part mold 230 on the insulation part mold 220 in order for a part of the insulation part 120 to be inserted into a shield receptor 231 of the shield part mold 230 while another part of the insulation part 120 is supported by the insulation part mold 220. For example, in the step S131, when the insulation part 120 is completely manufactured, some of the plurality of stacked insulation part molds 220 may be removed to stack the shield part mold 230 including the shield receptor 231. The remaining insulation part molds 220 may serve to support the insulation part 120 when the shield part mold 230 is stacked.

The step S130 of forming the shield part may further include a step S132 of filling the shield receptor 231 of the shield part mold 230 with the shield part 130 in a liquid phase containing a conductive particle. For example, referring to FIG. 13, the shield receptor 231 of the stacked shield part mold 230 may be filled with the shield part 130 in a liquid phase in the step S132.

Referring to FIG. 14, the step S130 of forming the shield part may further include a step S133 of aligning the magnetic flux concentration member 240 including the magnetic pads 241 at positions corresponding to the shield receptors 231 and hardening the shield part 130. For example, in the step S133, the magnetic flux concentration member 240 may be brought into close contact with the shield part mold 230 in order for the magnetic pads 241 to close the shield receptors 231.

In the step S133, the shield part mold 230 may be aligned in order for a part of the insulation part 120 to be inserted into the shield receptor 231 of the shield part mold 230 while another part of the insulation part 120 is supported by the shield part mold 230. As described above, the shield receptor 231 of the aligned shield part mold 230 may be filled with the shield part 130 in a liquid phase.

Also, in the step S133, the shield part 130 in a liquid phase may be hardened at a predetermined pressure and predetermined temperature. For example, the magnetic flux concentration member 240 may apply at least one of heat and pressure to the shield part 130 in a liquid phase. The shield part 130 in a liquid phase filled in each layer of a plurality of shield part molds 230 may be integrally formed with each other through a phase change caused by at least one of the heat and pressure applied to the shield part 130 in a liquid phase. That is, the shield part 130 in a liquid phase may be hardened to be integrally formed with each other by applying heat and pressure to the magnetic flux concentration member 240 in close contact with the shield part molds 230.

The step S130 of forming the shield part may further include a step S134 of separating the shield part mold 230 from the shield part 130. For example, in the step S134, the shield part 130 in a liquid phase filled in each of the plurality of shield part molds 230 may be hardened and then, the manufactured shield part 130 may be separated from the shield part molds 230.

In the descriptions above, the steps S110 to S130 may be divided into additional steps or combined into fewer steps depending on an embodiment. In addition, some of the steps may be omitted and the sequence of the steps may be changed if necessary.

The above description of the present disclosure is provided for the purpose of illustration, and it would be understood by a person with ordinary skill in the art to which the present invention belongs that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner, likewise, components described to be distributed can be implemented in a combined manner.

The recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise.

The scope of the present disclosure is defined by the following claims rather than by the detailed description of the embodiment, and it should be understood that all modifications and embodiments conceived from the meaning and scope of the claims and their equivalents are included in the scope of the present disclosure.

We claim:

1. A contactor for connection and signal transfer between conductors, comprising,
a core part configured to extend in a longitudinal direction, contains a conductive particle and be formed to be elastically deformable;
an insulation part configured to surround a transverse surface of the core part and be formed to be elastically deformable; and
a shield part configured to surround a transverse surface of the insulation part to be spaced apart from the core part, contains a conductive particle and be formed to be elastically deformable.

2. The contactor of claim 1,
wherein the core part, the insulation part, and the shield part are hardened by a phase change and integrally formed with each other.

3. The contactor of claim 1,
wherein the core part, the insulation part, and the shield part are concentrically cylindrical.

4. The contactor of claim 1,
wherein each of the core part and the shield part protrudes in the longitudinal direction compared to the insulation part.

5. The contactor of claim 1,
wherein the insulation part protrudes in the longitudinal direction compared to the shield part, and
the core part protrudes in the longitudinal direction compared to the insulation part.

6. The contactor of claim 1,
wherein the core part and the shield part are different from each other in at least one of physical properties including hardness, Young's modulus, and resistivity.

7. The contactor of claim 1,
wherein the conductive particles contained in the core part and the shield part are aligned in the longitudinal direction.

8. A method of manufacturing a contactor for connection and signal transfer between conductors, comprising,
forming a core part configured to extend in a longitudinal direction, contain a conductive particle and be elastically deformable;
forming an insulation part configured to surround a transverse surface of the core part and be elastically deformable; and
forming a shield part configured to surround a transverse surface of the insulation part to be spaced apart from the core part, contain a conductive particle and be elastically deformable.

9. The method of manufacturing a contactor of claim 8,
wherein the forming the core part includes,
filling a core receptor of a core part mold with the core part in a liquid phase containing the conductive particle;
aligning a magnetic flux concentration member including magnetic pads at positions corresponding to the core receptors and hardening the core part; and
separating at least a part of the core part mold from the core part.

10. The method of manufacturing a contactor of claim 9,
wherein the forming the insulation part includes,
aligning an insulation part mold on the core part mold in order for a part of the core part to be inserted into an insulation receptor of the insulation part mold while another part of the core part is supported by the core part mold.

11. The method of manufacturing a contactor of claim 8,
wherein the forming the insulation part includes,
filling an insulation receptor of an insulation part mold with the insulation part in a liquid phase;
hardening the insulation part; and
separating at least a part of the insulation part mold from the insulation part.

12. The method of manufacturing a contactor of claim 11,
wherein the forming the shield part includes,
aligning a shield part mold on the insulation part mold in order for a part of the insulation part to be inserted into a shield receptor of the shield part mold while another part of the insulation part is supported by the insulation part mold.

13. The method of manufacturing a contactor of claim 8,
wherein the forming the shield part includes,
filling a shield receptor of a shield part mold with the shield part in a liquid phase containing the conductive particle;
aligning a magnetic flux concentration member including magnetic pads at positions corresponding to the shield receptors and hardening the shield part; and
separating the shield part mold from the shield part.
